(19) United States
(12) Patent Application Publication
(10) Pub. No.: US 2006/0289146 A1
(43) Pub. Date: Dec. 28, 2006

(54) THERMAL MODULE INCORPORATING HEAT PIPE

(76) Inventor: Kuo-Hsien Wu, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/308,607

(22) Filed: Apr. 11, 2006

(30) Foreign Application Priority Data
Jun. 24, 2005 (CN) 200510035530.0

(51) Int. Cl. H05K 7/20

(52) U.S. Cl. 165/104.21; 165/104.33; 361/700; 257/715

(57) ABSTRACT

A thermal module for dissipating heat generated by a heat source includes a heat pipe and a heat sink. The heat pipe includes a vaporized portion thermally connected to the heat source for collecting the heat, a condensed portion for receiving the heat transmitted from the vaporized portion, and a heat transferring portion connecting the vaporized portion and the condensed portion, cross-sectional areas of a transitional portion for connecting the vaporized portion and the heat transferring portion being gradually changed. The heat sink is thermally connected to the condensed portion for cooling the condensed portion.

### FIELD OF THE INVENTION

This invention relates to a thermal module and, more particularly, to a thermal module incorporating a heat pipe for improving heat dissipating effectiveness thereof.

### DESCRIPTION OF RELATED ART

As computer technology continues to advance, electronic elements such as central processing units and chipsets in computers have faster operational speeds and larger functional capabilities. Heat produced within a computer enclosure increases greatly due to the advance in the operational speed. Operational stability of the electronic elements is deteriorated. In order to dissipate heat, various thermal modules are applied.

Referring to FIG. 6, a general thermal module 70 is illustrated. The thermal module 70 includes a heat sink 20, a fan 30, a heat receiver 40, and a heat pipe 50. Channels 200, 400 respectively defined in the heat sink 20 and the heat receiver 40 are applied for extensions of the heat pipe 50. The fan 30 is mounted on the heat sink 20 to blow heat away therefrom. The heat receiver 40 is attached to a heat source such as an electronic element (not shown) for collecting heat released from the heat source. The heat pipe 50 includes a heat transferring portion 500, a vaporized portion 502 and a condensed portion 504. The vaporized portion 502 and the condensed portion 504 are arranged at two opposite ends of the heat transferring portion 500 and are respectively inserted into the channels 200, 400. Working fluid (not shown) in a liquid state at a nonworking temperature, such as water, is filled within the heat pipe 50. The working fluid circulates in the heat pipe 50 when it is vaporized at the vaporized portion 502 and condensed at the condensed portion 504. The heat can be conducted away from the heat receiver 40 toward the heat sink 20 due to changing from the liquid state to a gaseous state. The heat sink 20 and the fan 30 dissipate the heat to surrounding atmosphere. Thermal resistance of a thermal junction between the heat pipe 50 and the heat source is increased because the heat pipe 50 is indirectly connected to the heat source via the heat receiver 40. The high thermal resistance results in lower heat dissipating effectiveness of the thermal module 70.

Referring also to FIG. 7, another thermal module 80 is developed in order to overcome the above-described shortcoming. The thermal module 80 includes a heat sink 22, a fan 32, and a heat pipe 52. The heat pipe 52 includes a heat transferring portion 520, a vaporized portion 522 and a condensed portion 524. The vaporized portion 522 and the condensed portion 624 are arranged at two opposite ends of the heat transferring portion 520. The vaporized portion 522 marches with the heat transferring portion 520 via a connecting position 526. The vaporized portion 522 is board-shaped and mounted to an electronic element (not shown) to receive heat. The heat is transmitted from the electronic element to the heat sink 22, and discharged to surrounding atmosphere by the fan 32. Thermal resistance of a thermal junction between the electronic element and the heat pipe 52 is lowered because the heat receiver 40 (shown in FIG. 1) is omitted. The heat dissipating effectiveness of the thermal module 80 is improved to some extent. However, areas, an extent of a planar region or of a surface of a solid measured in square units, of cross-sections from the vaporized portion 522 to the heat transferring portion 520 and adjacent to a connecting position 526 are acutely changed. Fluid resistance against the working fluid is heightened, and energy loss of the working fluid is greatly increased. Therefore, the heat dissipating effectiveness of the thermal module 80 is still lower.

Therefore, a thermal module having an improved heat dissipating effectiveness is needed.

### SUMMARY OF INVENTION

A thermal module for dissipating heat generated by a heat source includes a heat pipe and a heat sink. The heat pipe includes a vaporized portion thermally connected to the heat source for collecting the heat, a condensed portion for receiving the heat transmitted from the vaporized portion, and a heat transferring portion connecting the vaporized portion and the condensed portion, cross-sectional areas of a transitional portion for connecting the vaporized portion and the heat transferring portion being gradually changed. The heat sink is thermally connected to the condensed portion for cooling the condensed portion.

Other advantages and novel features will become more apparent from the following detailed description of preferred embodiments when taken in conjunction with the accompanying drawings, in which:

### BRIEF DESCRIPTION OF DRAWINGS

FIG. 1 is an exploded isometric view of a thermal module in accordance with a preferred embodiment, the thermal module including a heat pipe;

FIG. 2 is a top view of the heat pipe of FIG. 1;

FIG. 3 is a schematic view of a theoretic model of the general heat pipe of FIG. 2;

FIG. 4 is a schematic view of a curve of fluid energy loss index of the heat pipe of FIG. 2;

FIG. 5 is a schematic view of a theoretic model of the heat pipe of FIG. 3;

FIG. 6 is an isometric view of a general thermal module with a general heat pipe thereof; and

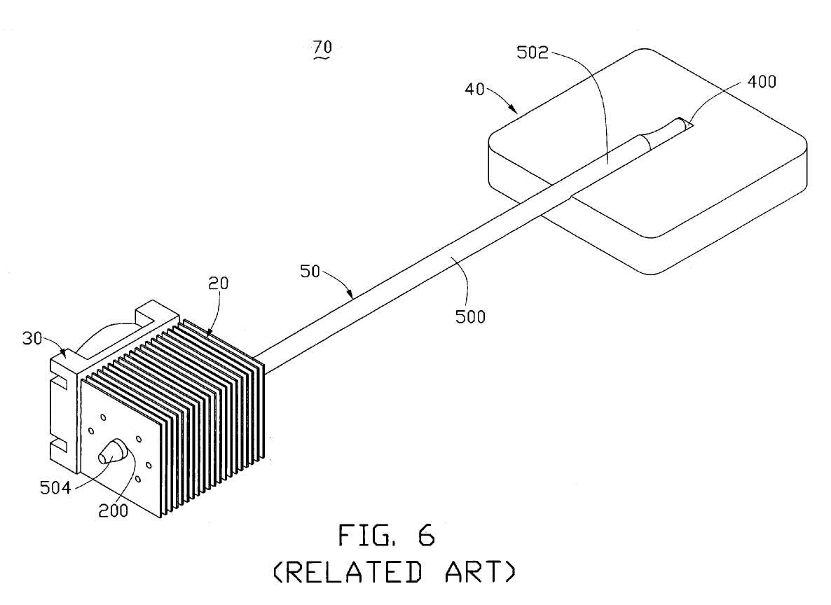

FIG. 7 is an isometric view of another general thermal module with another general heat pipe thereof.

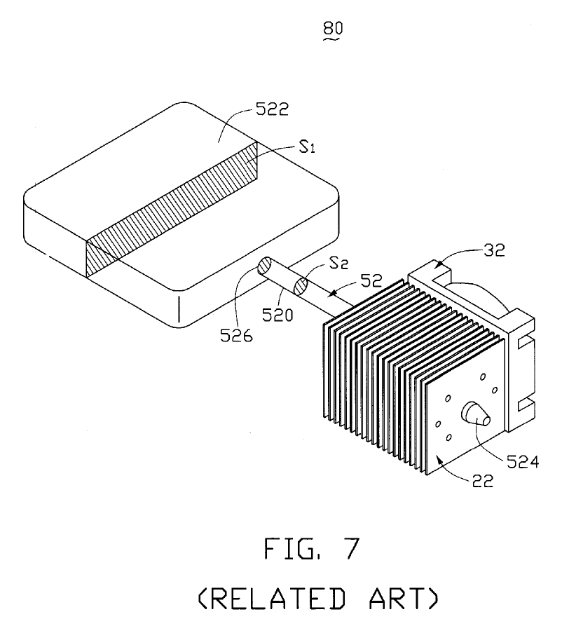

### DETAILED DESCRIPTION

Reference will now be made to the drawing figures to describe, at least, the preferred embodiment of the present thermal module incorporating a heat pipe, in detail.

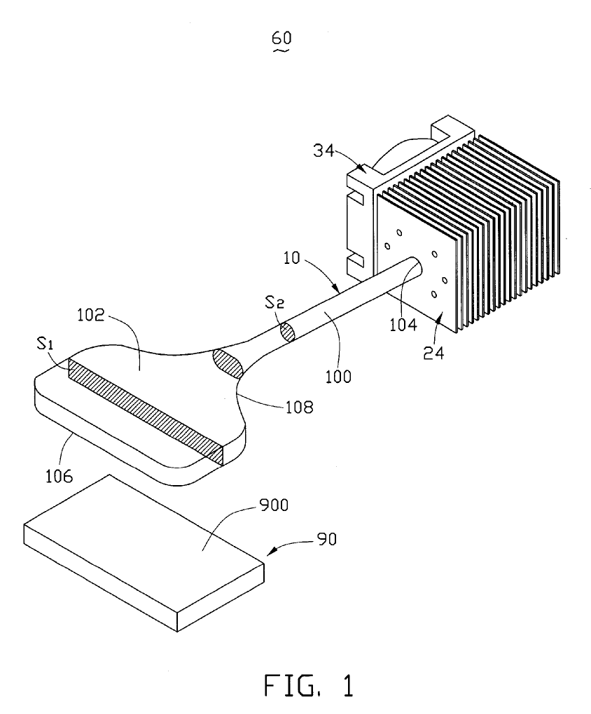

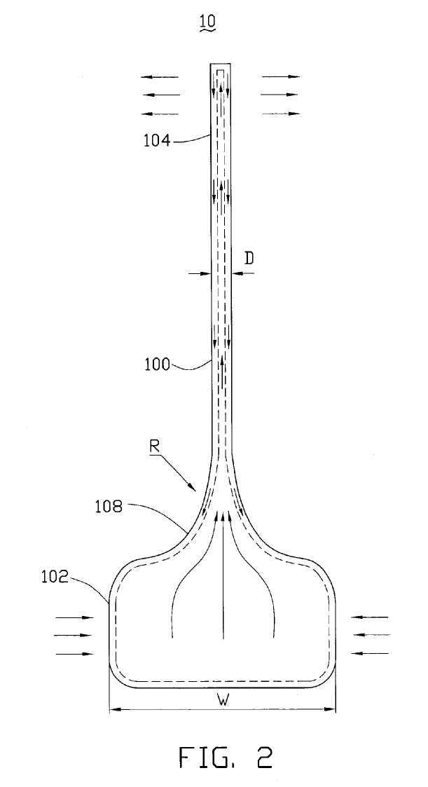

Referring to FIGS. 1 and 2, a thermal module 60 for dissipating heat generated by a heat source such as an electronic element 90 is illustrated. The thermal module 60 includes a heat pipe 10, a heat sink 24 and a fan 34. The heat pipe 10 is thermally connected to the electronic element 90 and the heat sink 24. The fan 34 is attached to the heat sink 24 for cooling the heat sink 24.

The heat pipe 10 is an elongated vessel filled with working fluid (not labeled) therein. The heat pipe 10 includes a heat transferring portion 100, a vaporized portion 102 and a condensed portion 104. The vaporized portion 102 and the condensed portion 104 are arranged at two ends of the heat transferring portion 100. The vaporized portion 102 includes an attaching plane 106 conformed to a corresponding upper plane 900 of the electronic element 90. An area of the attaching plane 106 is substantially equal to that of the upper plane 900. It is noted that the word “area” means an extent of a planar region or of a surface of a solid measured in square units in all chapters. A width W of the vaporized portion 102 is greater than a width D of the heat transferring portion 100. A transitional portion 108 interconnects the vaporized portion 102 and the heat transferring portion 100. Cross-sectional areas of the transitional portion 108 are gradually reduced from the vaporized portion 102 to the heat transferring portion 100.

In the preferred embodiment, the vaporized portion 102 is a cuboid, and the heat transferring portion 100 is a tube with a diameter D. The transitional position 108 is convergent from the vaporized portion 102 to the heat transferring portion 100, and has convergent contours with transitional radii R thereof.

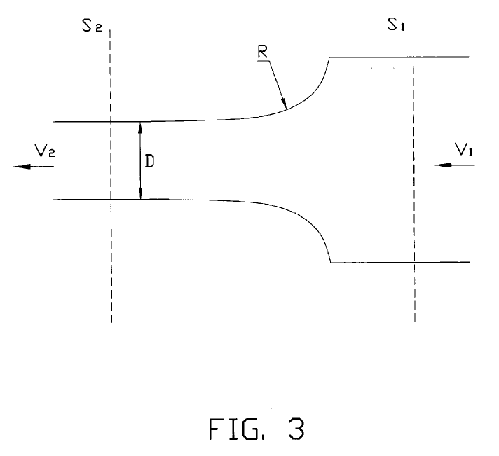

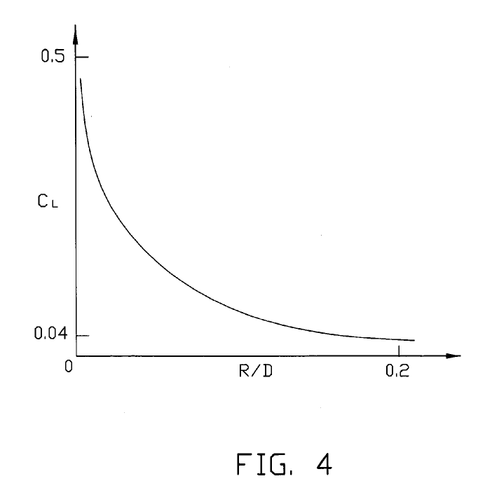

Referring to FIGS. 3 and 4, a theoretic model and an analysis curve for simulating and analyzing fluid energy loss H_{L1} of the working fluid therein are illustrated. The relationship between the fluid energy loss index C_{L} and R/D is defined as formula (1):
C_{L}=0.5e^{{-13R/D}} (1)

The fluid energy loss H_{L1} can be defined as formula (2):
H_{L1}=C_{L}(V₁-V₂)²/2g (2)

S₁, S₂ are cross-sections and respectively at opposite sides of the transitional position 108, V₁, V₂ are respectively velocities of the working fluid passing cross-sections S₁, S₂. If R/D fulfills the condition 0.2≦R/D≦1.0, the fluid energy loss index is lowered to 0<C_{L}≦0.0038. If R/D fulfills the condition R/D>1.0, the fluid energy loss index C_{L} is continuously and sluggishly decreased. If R/D fulfills the condition R/D<0.2, the fluid energy loss index C_{L} is exponentially increased. The fluid energy loss H_{L1} is thus markedly lowered when R/D fulfills the conditions 0.2≦R/D≦1.0 and R/D>1.0. Therefore, the condition R/D≧0.2 is acceptable for lowering the fluid energy loss H_{L1}.

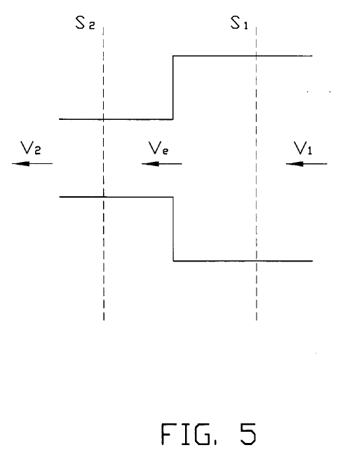

Contrastively, referring also to FIG. 5, another theoretic model for simulating fluid energy loss H_{L2} of the working fluid filled in the general heat pipe 80 of FIG. 2 is illustrated. The fluid energy loss H_{L2} can be deduced from following formulas (3)˜(8).
Q=V₁A₁=VₑA₁=V₂A₂ (3)

Q represents flux of the working fluid, V₁, Vₑ, V₂ represent respectively represent velocities of the working fluid passing a cross-section S₁, the transitional position 526 (shown in FIG. 2) between cross-sections S₁, S₂ and the cross-section S₂, A₁, A₂ respectively represent cross-sectional areas.
(Pₑ-P₂)A₂=pQ(V₂-Vₑ) (4)
y=pg (5)

y represents specific gravity, p represents density. Supposing Pₑ=P₁, Vₑ=V₁, formula (4) is converted to formula (6). P₁, Pₑ, P₂ respectively represent pressures that the working fluid is received at the cross-section S₁, the transitional position 526 and the cross-section S₂.
(P₁-P₂)/y=pQ(V₂-V₁)/pgA₂=Q(V₂-V₁)/gA₂ (6)
H_{L2}=(P₁-P₂)/y+(Z₁-Z₂)+(V₁²-V₂²)/2g (7)

Z₁, Z₂ respectively represent heights of the working fluid. Supposing Z₁=Z₂, formula (5) is converted to formula (6) as following:
H_{L}₂=Q(V₂-V₁)/gA₂+(V₁²-V₂²)/2g=(V₁-V₂)²/2g (8)

Comparing formulas (1) to (8), H_{L1}=C_{L}H_{L2}. Because 0<C_{L}≦0.0038, the fluid energy loss H_{L1} in the heat pipe 90 is much less than the fluid energy loss H_{L2} in the general heat pipe 80.

In use, the vaporized portion 102 of the heat pipe 90 is affixed to the electronic element 60 with thermally conductive grease (not shown) sandwiched therebetween. Thermal resistance of a thermal junction between the heat pipe 90 and the electronic element 60 is lowered. The vaporized portion 102 gains the heat from the electronic element 60. The heat transferring portion 100 transfers the heat from the vaporized portion 102 to the condensed portion 104 via the working fluid filled in the heat pipe 90. The heat sink 24 collects the heat from the condensed portion 104, and discharges the heat to the atmosphere around via a plurality of fins (not labeled) thereof. In order to enhance the cooling performance of the heat sink 24, the fan 34 may be applied to generate airflow to cool down the heat sink 24 more quickly. The working fluid reflows to the vaporized portion 102 to gain the heat again as soon as it is cooled at the condensed portion 104 by the heat sink 24 and fan 34.

In alternative embodiments, the vaporized portion 102 may be configured as other general configurations such as a flat column. The condensed portion 524 may be also configured as the vaporized portion 522. In addition, the fan 34 may be omitted in case the heat sink 24 is sufficient for cooling the heat pipe 50 quickly. The heat sink 24 may be configured as other general configurations besides the configurations illustrated in the FIG. 3.

The embodiments described herein are merely illustrative of the principles of the present invention. Other arrangements and advantages may be devised by those skilled in the art without departing from the spirit and scope of the present invention. Accordingly, the present invention should be deemed not to be limited to the above detailed description, but rather by the spirit and scope of the claims that follow, and their equivalents.

What is claimed is:

1. A thermal module for dissipating heat generated by a heat source comprising: a heat pipe including a vaporized portion thermally connected to the heat source for collecting the heat, a condensed portion for receiving the heat transmitted from the vaporized portion, and a heat transferring portion connecting the vaporized portion and the condensed portion, cross-sectional areas of a transitional portion for connecting the vaporized portion and the heat transferring portion being gradually changed; and
a heat sink thermally connected to the condensed portion for cooling the condensed portion.

2. The thermal module as claimed in claim 1, wherein a ratio of a radius of the transitional portion to a cross-sectional width of the heat transferring portion is greater than or equal to 0.2.

3. The thermal module as claimed in claim 2, wherein the ratio is less than or equal to 1.0.

4. The thermal module as claimed in claim 1, wherein the vaporized portion includes an attaching plane conforming to a corresponding plane of the heat source.

5. The thermal module as claimed in claim 4, wherein an area of the attaching plane is substantially equal to the corresponding plane of heat source.

6. The thermal module as claimed in claim 1, wherein the vaporized portion and the vaporized portion are integrally formed with the heat transferring portion.

7. The thermal module as claimed in claim 1, wherein cross-sectional areas of another transitional portion for connecting the condensed portion and the heat transferring portion are gradually changed.

8. The thermal modules as claimed in claim 1, further comprising a fan attached on a side of the heat sink for generating airflow to discharging heat to surrounding atmosphere.

9. A heat pipe for dissipating heat generated by a heat source comprising:
a vaporized portion thermally connected to the heat source for collecting the heat;
a condensed portion for receiving the heat transmitted from the vaporized portion; and
a heat transferring portion connecting the vaporized portion and the condensed portion, cross-sectional areas from the vaporized portion to the heat transferring portion being gradually changed.

10. The heat pipe as claimed in claim 9, wherein a ratio of a radius of from the vaporized portion to the heat transferring portion to a cross-sectional width of the heat transferring portion is greater than or equal to 0.2.

11. The heat pipe as claimed in claim 10, wherein the ratio is less than or equal to 1.0.

12. The heat pipe as claimed in claim 10, wherein the vaporized portion has an attaching plane in contact a corresponding plane of the heat source.

13. The heat pipe as claimed in claim 12, wherein an area of the attaching plane is substantially equal to the corresponding plane of the heat source.

14. The heat pipe as claimed in claim 9, wherein cross-sectional areas of another transitional portion for connecting the condensed portion and the heat transferring portion are gradually changed.

15. The heat pipe as claimed in claim 9, wherein the vaporized portion, heat transferring portion and the vaporized portion are integrally formed.

16. A heat pipe for dissipating heat generated by a heat source comprising:
a vaporized portion thermally connected to the heat source for collecting the heat;
a condensed portion for receiving the heat transmitted from the vaporized portion;
a heat transferring portion connecting the vaporized portion and the condensed portion; and
a transitional position being convergent from the vaporized portion to the heat transferring portion and having convergent contours with transitional radii.

17. The heat pipe as claimed in claim 16, wherein a ratio of a transitional radius of the transitional portion to a cross-sectional width of the heat transferring portion is greater than or equal to 0.2.

18. The heat pipe as claimed in claim 17, wherein the transitional ratio is less than or equal to 1.0.

19. The heat pipe as claimed in claim 16, wherein the vaporized portion has an attaching plane in contact a corresponding plane of the heat source.

20. The heat pipe as claimed in claim 19, wherein an area of the attaching plane is substantially equal to the corresponding plane of the heat source.
